(19) United States
(12) Patent Application Publication
(10) Pub. No.: US 2017/0227617 A1
(43) Pub. Date: Aug. 10, 2017

(54) METHOD AND APPARATUS FOR MANIPULATING ELECTROPERMANENT MAGNETS FOR MAGNETIC RESONANCE IMAGING AND IMAGE GUIDED THERAPY

(71) Applicant: Weinberg Medical Physics, Inc., North Bethesda, MD (US)

(72) Inventors: Irving N. Weinberg, Bethesda, MD (US); Aleksandar Nelson Nacev, Bethesda, MD (US)

(73) Assignee: Weinberg Medical Physics, Inc.

(21) Appl. No.: 15/427,426

(22) Filed: Feb. 8, 2017

Related U.S. Application Data
(60) Provisional application No. 62/292,945, filed on Feb. 9, 2016.
(60) Provisional application No. 62/329,521, filed on Apr. 29, 2016.

(51) Int. Cl. G01R 33/381

(52) U.S. Cl. CPC G01R 33/381

(57) ABSTRACT

Disclosed embodiments provide an apparatus and method for creating or modifying a magnetic field in a region of interest including one or more arrays of magnetizable components in which at least one of the magnetizable components has a substantial remanent magnetization, the level of which being controllable and variable in space and/or time through imposition of electrical currents in electrically conductive components located in proximity to one or more of the magnetizable components.

### CROSS REFERENCE AND PRIORITY CLAIM

This patent application claims priority to U.S. Provisional Application Provisional Patent Application No. Patent Application Ser. No. 62/292,945, entitled “METHOD AND APPARATUS FOR MANIPULATING ELECTROPERMANENT MAGNETS FOR MAGNETIC RESONANCE IMAGING AND IMAGE GUIDED THERAPY,” filed Feb. 9, 2016, and U.S. Provisional Patent Application No. 62/329,521, entitled “METHOD AND APPARATUS FOR MANIPULATING ELECTROPERMANENT MAGNETS FOR MAGNETIC RESONANCE IMAGING AND IMAGE GUIDED THERAPY,” and filed Apr. 29, 2016, the disclosures of which being incorporated herein by reference in their entirety.

### FIELD

Disclosed embodiments provide a method and apparatus for manipulating electropermanent magnets for magnetic resonance imaging and image guided therapy.

### BACKGROUND

Magnetic Resonance (MR) imaging systems use a main magnetic field B₀ to align protons or electrons prior to procedures that affect the net magnetization of these aligned species. The strength and spatial uniformity of this aligning magnetic field specifies the imaging volume and largely determines the signal-to-noise ratio of the images. To simplify pulse sequence design and improve signal strength, this main magnetic field B₀ is designed to be as uniform and as strong as possible within the imaging volume. To accomplish this feat, conventional MR systems typically use superconducting electromagnets arranged in a solenoid around an imaging bore. Other types of MR systems have employed resistive electromagnets or permanent magnets to create the main magnetic fields.

In general, with conventional MRI systems, it is difficult and sometimes dangerous to power down the main magnetic field. Permanent magnetic sources that are derived from magnetically hard materials are not demagnetized in a clinical setting due to the large energy requirement to counteract their remanent magnetization.

### SUMMARY

Disclosed embodiments provide an apparatus and method for creating or modifying a magnetic field in a region of interest comprising one or more arrays of magnetizable components in which at least one of the magnetizable components has a substantial remanent magnetization, the level of which being controllable and variable in space and/or time through imposition of electrical currents in electrically conductive components located in proximity to one or more of the magnetizable components.

### BRIEF DESCRIPTION OF THE FIGURES

The detailed description particularly refers to the accompanying figures in which:

FIG. 1 illustrates a disclosed embodiment in which a component made of magnetizable material is provided in close proximity to an electrically conductive material to form an electropermanent assembly.

FIG. 2 illustrates a disclosed embodiment in which a component made of a soft magnetic material is surrounded at least in part by an electrically conductive material and is in close proximity to another component made from a hard magnetic material.

FIG. 3 illustrates an example of a methodology performed in accordance with the disclosed embodiment for applying and controlling a magnetic field generated in a region of interest.

FIG. 4 illustrates a disclosed embodiment in which a component made of a soft magnetic material is in close proximity to another soft magnetic material and a hard magnetic material.

### DETAILED DESCRIPTION

As explained above, conventional MR systems, have an always-on high magnetic field that is present within the imaging area. This situation creates safety concerns for the clinical environment, and hinders the ability for the same MR system to perform both imaging and magnetic image guidance of magnetizable materials. Disclosed embodiments address these issues and provide a technical utility to manipulate electropermanent magnets for magnetic resonance imaging and image guided therapy.

Combinations of magnetic materials that retain their magnetization (e.g., ferromagnetic, diamagnetic, antiferromagnetic materials) and electromagnets, termed “electropermanent magnets,” have been used as switchable linkages within micro-robot assemblies, as taught by A. N. Knaian in the 2010 doctoral thesis from the Massachusetts Institute of Technology entitled “Electropermanent Magnetic Connectors and Actuators: Devices and Their Application in Programmable Matter” (incorporated by reference in its entirety herein).

Electropermanent magnets have the property that, once activated with an electrical current, the electropermanent magnet has a remanent magnetization until an opposing electrical current is introduced to change the remanent magnetization. Electropermanent magnets have been constructed so as to either be on or off (i.e., fully magnetized or demagnetized—an electrical switch), without a continuum within the magnetic field strength between those two states.

For the purposes of this specification disclosure, the term “remanent magnetization” is defined as the retained magnetization of a magnetized material after the externally applied magnetic field that magnetized the material was removed. For the purposes of this specification disclosure, the term “soft magnetic material” is defined as a material whose remanent magnetization can be readily changed by imposing an external magnetic field. Likewise, the term “hard magnetic material,” for the purposes of this specification disclosure, refers to a material with a remanent magnetization that changes less than a “soft magnetic material” in a similar external magnetic field.

For the purposes of this specification disclosure, a representative soft magnetic material is Alnico, and a representative hard magnetic material is NdFeB. For the purposes of this specification disclosure, the term “electropermanent assembly” is defined as an assembly of electrically conductive and magnetizable components and/or materials that retain substantial (for example, 10% of maximal) magnetization after current has ceased in the electrically conductive component. For the purposes of this specification disclosure, the term “electrically conductive” includes electrically conductive and superconductive materials. For the purposes of this specification disclosure, the term “region of interest” is defined as the volumetric space in which a user may obtain images and/or manipulate magnetizable materials (for example, particles).

For the purposes of this specification disclosure, the phrase “imaging within a region of interest” includes using the electrical or magnetic properties of materials in that region of interest to provide information about the location or state of those materials. Examples of “imaging within a region of interest” includes magnetic resonance imaging, magnetic particle imaging, or other methods such as non-magnetic related imaging methods, such as Computerized Tomography (CT). These images may be obtained using magnetic resonance imaging of nuclei, electrons, other materials, or via magnetic particle imaging. The region of interest can be a single volumetric space or be composed of multiple volumes which may or may not be contiguous.

Disclosed embodiments utilize one or more arrays, in which at least one array contains one or more electropermanent assemblies.

FIG. 1 demonstrates one disclosed embodiment of the innovative concept in which a component 100 is made of magnetizable material. Component 100 may be in close proximity to an electrically conductive material 110 to form an electropermanent assembly 120. In accordance with at least one embodiment, that proximity may be less than 1 centimeter.

As illustrated in the embodiment shown in FIG. 1, a disclosed embodiment may provide and utilize one or more electropermanent assemblies 120 composed of a magnetic component 100, which may be surrounded by electrically conductive material 110. The magnetic component 100 may be comprised of a soft magnetic material. Optionally, the electrically conductive material 110 may be one or more wires, or one or more channels of copper or silver, or of another electrically conductive material deposited near component 100.

In accordance with at least one embodiment, a collection of one or more of these electropermanent assemblies 120 can then be arranged into an electropermanent array 130, in proximity to a region of interest 140, e.g., less than 1 meter.

In operation, an electrical current can be sent through conductor 110 to magnetize the magnetically soft component 100 to a given magnetization. Once the magnetic material 100 has reached the desired magnetization, the electropermanent assembly 120 composed of components 100 and 110 can be depowered (e.g., by removing the current source from the conductor) allowing the magnetization within the magnetic component 100 to decrease to a desired remanent magnetization level.

In accordance with at least one embodiment, the electromagnetic field produced by conductive materials 110 can be adjusted by a user (via controlling equipment) or automated algorithm by a computer (that provides an automated or semi-automated controller) to precisely control the remanent magnetization and resulting magnetic field in the region of interest. Information about the B-H response curve of the magnetic materials within the magnetic component 100 may be incorporated into the adjustment algorithm.

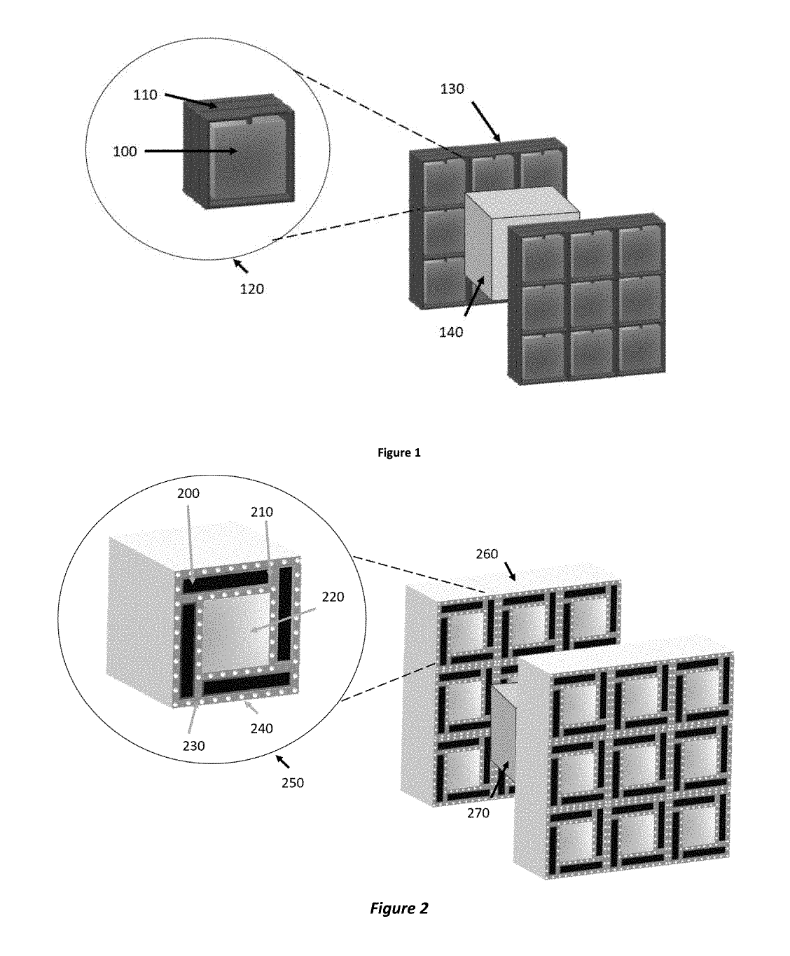

FIG. 2 illustrates another disclosed embodiment of the innovative concept in which component 200, here made of a soft magnetic material, is surrounded at least in part by an electrically conductive material 210, and in which a hard magnetic material component 220 is in proximity to the soft magnetic material component 200. Optionally, the proximity may be less than 15 cm.

Housing 230 stabilizes or otherwise physically holds components 210, 220, 200. Housing 230 may include one or more cooling paths 240 in which liquid or gaseous coolants may flow, or through which heat may travel via a thermally-conductive material.

The combination of these soft and hard magnetic materials and electrically conducting material affixed within a housing form an electropermanent assembly 250. One or more electropermanent assemblies 250 may be combined into an array 260.

The combination of housing and hard and soft magnetic components may comprise an electropermanent assembly 250, of which one or more assemblies 250 can be configured into one or more arrays 260 for generation of a magnetic field in region of interest 270. Because the one or more soft magnetic components 200 may be positioned in proximity to one or more magnetically hard components 220, the magnetic field of the hard component 220 may reinforce, add to, or otherwise affect the magnetic field in component 200.

Cooling channels 240 in housing 230 may be used to dissipate heat and/or to cool the electrically conductive materials 210 so as to reduce the resistivity of the conductive elements (including to the point of superconducting, i.e., no resistance) or to increase the magnetization of the magnetic components 200 and/or 220.

The arrays may be located on a single side of the region of interest 270 or can surround the associated region on multiple sides. The arrays may produce a magnetic field that has a direction that is not parallel (for example perpendicular) to the closest face of the arrays.

The one or more arrays 260 of electropermanent assemblies may create a magnetic field suitable for magnetic resonance imaging within the region of interest. This magnetic field can be arranged in any direction including but not limited to being perpendicular to the closest face of the arrays 260. For example, this magnetic field may be non-parallel to the face of the array.

The one or more arrays 260 of electropermanent assemblies may be planar as shown in FIGS. 1 and 2, or curvilinear, or arranged in a toroid, or in a uni-planar, bi-planar, tri-planar, or other configuration, in order to create a desired magnetic field within the region or regions of interest. For example, the uni-planar arrangement could implement a single-sided MRI. Such an implementation is technically different from the single-sided MRI technology, for example, that disclosed in U.S. Pat. No. 6,977,503 to P. J. Prado, in a number of meaningful ways. First, the magnetic field surfaces in the prior art are required to be parallel to the surface of the magnet assembly, while the presently disclosed embodiments do not impose such a directional requirement.

Secondly, the presently disclosed embodiments do not require that the magnetic field be static, as evidenced by the disclosed embodiments' use of electropermanent magnets, which have magnetic fields that may change in time. In accordance with at least one embodiment, varying levels of magnetic energy produced by the current flowing through conductive materials 110 or 210 can be stored within the magnetic materials 100 or 200. Utilizing one or a combination of these electropermanent assemblies 120 or 250 can create a region of interest 140 or 270 imbued with a magnetic field suitable for imaging within a region of interest.

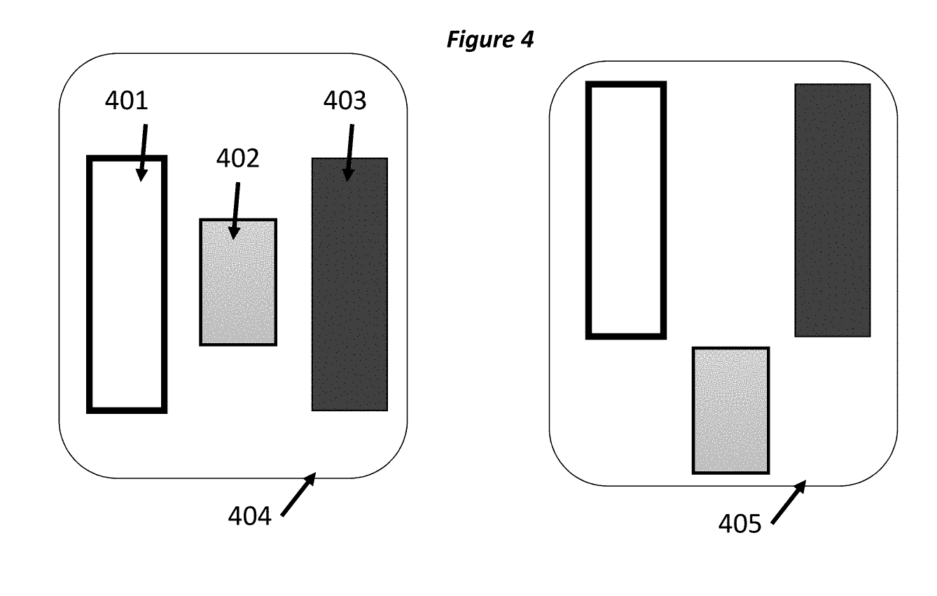

In another embodiment as shown in FIG. 4, a soft magnetic material 401 can be in close proximity to an additional soft magnetic material 402 and a hard magnetic material 403. In one arrangement 404, the magnetic field from the magnetized hard magnetic material 403 may induce a magnetization within the soft magnetic material 401. By changing the proximity of either of these secondary magnetic materials (402 or 403) as shown in 405, the induced magnetization within the first soft magnetic material 401 can be changed. Therefore, the relative mechanical movements of these magnets can be controlled and adjusted so that a desired magnetic field at a region of interest can be created. These relative mechanical movements may be made using one or more known linkages, for example, an actuator based on any number of principals including hydraulics.

In accordance with at least one embodiment, the magnetization of one or more soft magnetic components 100 or 200 may be modified by changing the position and/or physical orientation of one or more nearby hard magnetic components. A collection of one or more of these assemblies of magnetic components can then be arranged into the equivalent of an electropermanent array 130 or 260.

In accordance with at least one embodiment, conductive material 110 or 210 may be energized with current, so that magnetic component 100 or 200 will be magnetized in a direction and/or magnitude, which may be selected by a user (via controlling equipment) or automated algorithm by a computer (that provides an automated or semi-automated controller). After the magnetic component 100 or 200 is magnetized, conductive material 110 or 210 can be de-energized while the magnetization within material 100 or 200 retains remanent magnetization, which may be selected by a user (via controlling equipment) or automated algorithm by a computer (that provides an automated or semi-automated controller).

In accordance with at least one embodiment, the magnetic field produced by one or more arrays 130 within the region of interest 140 can be reduced or increased by adjusting the magnetization of one or more electropermanent assemblies 120. Similarly, the magnetic field produced by one or more arrays 260 within the region of interest 270 can be reduced or increased by adjusting the magnetization of one or more electropermanent assemblies 250.

Disclosed embodiments may be used to generate a magnetic field for the purposes of magnetic resonance imaging and/or magnetic particle imaging and/or manipulation of magnetizable materials (for example, magnetic particles or nanoparticles). Unlike prior art as taught by Knaian (cited above) in which an electropermanent assembly is intended for use in either fully magnetized or demagnetized states, the present invention permits the electropermanent assembly to have gradations in remanent magnetizations, where the degree of remanent magnetization is modifiable by user (via controlling equipment) or automated algorithm by a computer (that provides an automated or semi-automated controller).

Disclosed embodiments may use one or more arrays of electropermanent assemblies in order to provide a means of creating and modifying a magnetic field near the array within a region of interest, in which the spatial properties of said magnetic field can be varied in time and space. Disclosed embodiments may be employed to select a region of interest for magnetic resonance imaging or magnetic particle imaging, or to establish high uniformity of the magnetic field within the region of interest, or to propel particles within the region of interest. Such particles may be provided for therapeutic purposes, for example, by carrying medications to/in the region of interest, generating electrical fields or disrupting biofilms, or stabilizing tissues, or other therapeutic mechanisms in or near the region of interest. The array composed of electropermanent assemblies can be turned off or diminished as a safety feature (to keep magnetizable materials from being attracted to said array), or to permit interleaving of imaging sequences of different species (e.g., differing nuclei, magnetic particle types, or electrons), or to permit imaging to be interleaved with propulsion pulse sequences (utilizing gradients that may be established by the electropermanent array or other magnetic field sources).

One or more arrays of electropermanent assemblies (e.g., 130 or 260 discussed above) can be re-magnetized by application of current through the electrically conductive components 110 or 210 to create a magnetic field in a region of interest 140 or 270 that is suitable for imaging. The magnetic field can be varied in time and space for magnetic guidance and/or propulsion of magnetizable particles, either through typical attraction of said particles or via temporary repulsion (as taught by A. Nacev, P. Y. Stepanov, and I. N. Weinberg, in the 2015 article “Dynamic Magnetic Inversion Concentrates Ferromagnetic Rods to Central Targets,” (incorporated by reference in its entirety herein) published in the journal Nano Letters.

It is understood that sensors may be present in or near the region of interest 140 or 270 so as to implement a feedback control algorithm. Feedback may alternatively be obtained from MR signals. Feedback loops for conventional MRI systems have been used to improve temporal and spatial homogeneity of the desired magnetic field configuration, as taught by S. Afach in the 2014 article published in the Journal of Applied Physics entitled, “Dynamic stabilization of the magnetic field surrounding the neutron electric dipole moment spectrometer at the Paul Scherrer Institute” (incorporated by reference in its entirety herein).

Being able to turn off or significantly reduce the magnetic field within the region of interest is useful for safety when bulky or sharp magnetizable objects are nearby. It is understood that changes in the magnetic resonance signals obtained as a result of changes of magnetic field in the region of interest 140 or 270 may be detected in order to ascertain the presence of nearby magnetizable materials, and thereby act as a trigger to demagnetize or significantly reduce the magnetic field in the vicinity of the apparatus for safety reasons.

Although the above discussion pertained to use of the apparatus to create the main magnetic field B₀, the apparatus can implement other functional components of a traditional MR or magnetic particle imaging system, including but not limited to shimming magnets and magnetic field gradient coils. In a traditional MR system, separate gradient coils are used to add gradient magnetic fields (whose magnitude and direction usually varies in space and time) to the main magnetic field B₀ (which is usually uniform in space and time within a region of interest) in order to realize an effective magnetic field (which varies in space and time). The proposed apparatus can effectively generate a magnetic field that would vary in space and time, without the need for additional electromagnetic gradient coils. It is understood that rapid changes in the magnetic field implemented with the invention can be made quickly enough so as not to cause nerve stimulation, as taught by I. N. Weinberg in U.S. Pat. No. 8,154,286 and other patents and patent applications related by priority claims (incorporated by reference in its entirety herein).

In accordance with at least one embodiment, a method for creating a magnetic field within a region of interest is provided in which electrical current is applied in proximity to at least one magnetizable components in one or more arrays in order to change the remanent magnetization of one or more magnetizable components. The one or more arrays of electropermanent assemblies may create a magnetic field suitable for magnetic resonance imaging and/or magnetic particle imaging and/or manipulation of magnetizable materials (for example, magnetic particles or nanoparticles) within a region of interest.

That magnetic field can be diminished in the vicinity of the one or more arrays and/or varied rapidly so as not to cause nerve stimulation as taught by I. N. Weinberg in U.S. Pat. No. 8,154,286 and other patents and patent applications related by priority claims.

Furthermore, adjustment of the magnetic field may be performed using one or more feedback control algorithms incorporating magnetic field measurements to adjust the magnetization of at least one magnetizable component in the one or more assemblies.

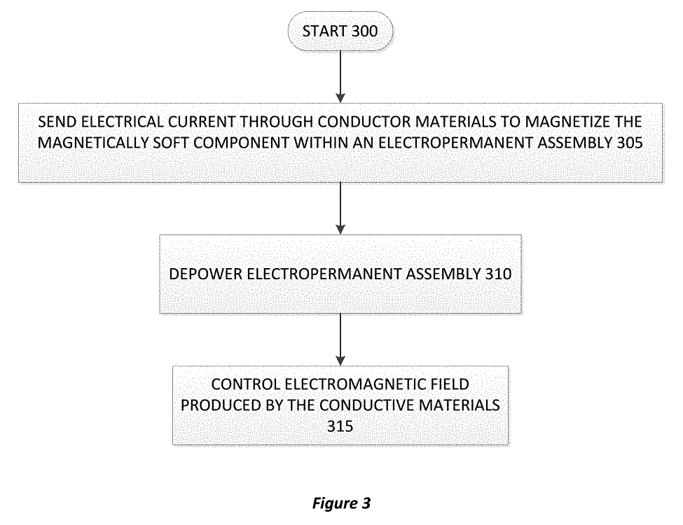

As illustrated in FIG. 3, such a method may begin at 300, following positioning of one or more electropermanent assemblies proximate to a region of interest, and control may proceed to 305, at which an electrical current can be sent through conductor materials to magnetize the magnetically soft component within an electropermanent assembly (see for example FIG. 1) to a given magnetization. Once the magnetic material 100 has reached the desired magnetization (as could be measured by one or more sensors), control may proceed to 310, at which the electropermanent assembly can be depowered (e.g., by removing the current source from the conductive materials) allowing the magnetization within the magnetic component to decrease to a desired remanent magnetization level (as could be measured by one or more sensors).

Operation may continue to 315, at which the electromagnetic field produced by the conductive materials can be adjusted by a user (via controlling equipment) or automated algorithm by a computer (that provides an automated or semi-automated controller) in order to precisely control the remanent magnetization and resulting magnetic field in the field of interest. Additionally, or in the alternative, the magnetization of one or more soft magnetic components or may be modified by changing the position and/or physical orientation of one or more nearby hard magnetic components.

As explained above, the arrays may be located on a single side of the region of interest or can surround the associated region on multiple sides. The arrays may produce a magnetic field that has a direction that is not parallel (for example perpendicular) to the closest face of the arrays. This magnetic field can be arranged in any direction including but not limited to being perpendicular to the closest face of the arrays. For example, this magnetic field may be non-parallel to the face of the array.

Disclosed embodiments may use one or more arrays of electropermanent assemblies in order to provide a means of creating and modifying a magnetic field near the array within a region of interest, in which the spatial properties of said magnetic field can be varied in time and space. Disclosed embodiments may be employed to select a region of interest for magnetic resonance imaging or magnetic particle imaging, or to establish high uniformity of the magnetic field within the region of interest, or to propel particles within the region of interest. The array composed of electropermanent assemblies can be turned off or diminished as a safety feature (to keep magnetizable materials from being attracted to said array), or to permit interleaving of imaging sequences of different species (e.g., differing nuclei, magnetic particle types, or electrons), or to permit imaging to be interleaved with propulsion pulse sequences (utilizing gradients that may be established by the electropermanent array or other magnetic field sources).

One or more arrays of electropermanent assemblies can be re-magnetized by application of current through the electrically conductive components to create a magnetic field in a region of interest that is suitable for imaging. The magnetic field can be varied in time and space for magnetic guidance and/or propulsion of magnetizable particles, either through typical attraction of said particles or via temporary repulsion. Being able to turn off or significantly reduce the magnetic field within the region of interest is useful for safety when bulky or sharp magnetizable objects are nearby. It is understood that changes in the magnetic resonance signals obtained as a result of changes of magnetic field in the region of interest may be detected in order to ascertain the presence of nearby magnetizable materials, and thereby act as a trigger to demagnetize or significantly reduce the magnetic field in the vicinity of the apparatus for safety reasons.

It should be understood that the operations explained herein may be implemented in conjunction with, or under the control of, one or more general purpose computers running software algorithms to provide the presently disclosed functionality and turning those computers into specific purpose computers.

Moreover, those skilled in the art will recognize, upon consideration of the above teachings, that the above exemplary embodiments may be based upon use of one or more programmed processors programmed with a suitable computer program. However, the disclosed embodiments could be implemented using hardware component equivalents such as special purpose hardware and/or dedicated processors. Similarly, general purpose computers, microprocessor based computers, micro-controllers, optical computers, analog computers, dedicated processors, application specific circuits and/or dedicated hard wired logic may be used to construct alternative equivalent embodiments.

Moreover, it should be understood that control and cooperation of the above-described components may be provided using software instructions that may be stored in a tangible, non-transitory storage device such as a non-transitory computer readable storage device storing instructions which, when executed on one or more programmed processors, carry out the above-described method operations and resulting functionality. In this case, the term non-transitory is intended to preclude transmitted signals and propagating waves, but not storage devices that are erasable or dependent upon power sources to retain information.

Those skilled in the art will appreciate, upon consideration of the above teachings, that the program operations and processes and associated data used to implement certain of the embodiments described above can be implemented using disc storage as well as other forms of storage devices including, but not limited to non-transitory storage media (where non-transitory is intended only to preclude propagating signals and not signals which are transitory in that they are erased by removal of power or explicit acts of erasure) such as for example Read Only Memory (ROM) devices, Random Access Memory (RAM) devices, network memory devices, optical storage elements, magnetic storage elements, magneto-optical storage elements, flash memory, core memory and/or other equivalent volatile and non-volatile storage technologies without departing from certain embodiments. Such alternative storage devices should be considered equivalents.

While certain illustrative embodiments have been described, it is evident that many alternatives, modifications, permutations and variations will become apparent to those skilled in the art in light of the foregoing description. Accordingly, the various embodiments of, as set forth above, are intended to be illustrative, not limiting. Various changes may be made without departing from the spirit and scope of the invention.

1. An apparatus for creating or modifying a magnetic field in a region of interest, the apparatus comprising:
one or more arrays of magnetizable components in which at least one of the magnetizable components has a substantial remanent magnetization, wherein the one or more arrays also include electrically conductive components located in proximity to one or more of the magnetizable component; and
a controller for controlling the remanent magnetization,
wherein the remanent magnetization is varied in space and/or time through imposition of electrical currents in the electrically conductive components located in proximity to one or more of the magnetizable components to control the magnetic field in the region of interest.

2. The apparatus of claim 1, further comprising cooling paths provided in the one or more arrays that are positioned to decrease resistance of the electrically conductive components and/or increase magnetization of one or more magnetizable components.

3. The apparatus of claim 1, wherein the remanent magnetization of at least one of the one or more magnetizable components is variable under the control of the controller.

4. The apparatus of claim 1, wherein the controller controls the magnetic field in the region of interest in time and/or space.

5. The apparatus of claim 1, wherein at least one of the magnetizable components is comprised at least in part of a hard magnetic material and at least one magnetizable component is comprised as least in part of a soft magnetic material.

6. The apparatus of claim 1, wherein at least one magnetizable component is mechanically movable to adjust the magnetization of another soft magnetic material.

7. The apparatus of claim 1, wherein the magnetic field in the region of interest is suitable for magnetic resonance imaging and is not parallel to the closest face of the apparatus.

8. The apparatus of claim 1, wherein the magnetic field in the region of interest is suitable for magnetic resonance imaging and is not perpendicular to the closest face of the apparatus.

9. The apparatus of claim 1, wherein the magnetic field in the region of interest is suitable for propulsion of particles.

10. The apparatus of claim 1, where the apparatus is disposed on only one side of the region of interest.

11. A method for creating or modifying a magnetic field in a region of interest, the method comprising:
controlling one or more arrays of magnetizable components in which at least one of the magnetizable components has a substantial remanent magnetization, wherein the one or more arrays also include electrically conductive components located in proximity to one or more of the magnetizable component;
wherein the remanent magnetization controlled to be varied in space and/or time through imposition of electrical currents in the electrically conductive components located in proximity to one or more of the magnetizable components to control the magnetic field in the region of interest.

12. The method of claim 11, wherein the variation of the remanent magnetization diminishes the magnetic field in a vicinity of the one or more arrays in the presence of nearby magnetizable materials.

13. The method of claim 11, wherein the variation of the remanent magnetization varies the magnetic field within the region of interest rapidly so as not to cause nerve stimulation.

14. The method of claim 11, wherein the variation of the remanent magnetization is implemented using a feedback control algorithm incorporating magnetic field measurements used to adjust the magnetization of at least one magnetizable component.

15. The method of claim 11, further comprising mechanically moving at least one magnetizable component to adjust the magnetization of another soft magnetic material.

16. The apparatus of claim 11, wherein the magnetic field in the region of interest is suitable for propulsion of particles.
